(19) United States
(12) Patent Application Publication
(10) Pub. No.: US 2024/0040726 A1
(43) Pub. Date: Feb. 1, 2024

(54) LOCKING CARD TRAYS

(71) Applicant: Hewlett-Packard Development Company, L.P., Spring, TX (US)

(72) Inventors: Rong-De Wang, Taipei City (TW); Chien-Pai Lai, Taipei City (TW); Chen-Ta Hung, Taipei City (TW); Chung-Hua Ku, Taipei City (TW)

(21) Appl. No.: 17/877,480

(22) Filed: Jul. 29, 2022

(51) Int. Cl. H05K 5/02

(52) U.S. Cl. CPC H05K 5/0256

(57) ABSTRACT

In some examples, a locking card tray can include a first elongated side, a second elongated side located opposite the first elongated side, a first end side connected to the first elongated side and the second elongated side, a rack tray, and an elastic deformable member, where in response to an integrated circuit card being received by the rack tray, the elastic deformable member is to rotate from a first position to a second position such that the elastic deformable member protrudes from the locking card tray.

### BACKGROUND

Users of computing devices may utilize their computing devices for various purposes. A computing device can allow a user to utilize computing device operations for work, education, gaming, multimedia, and/or other general use. Certain computing devices can be portable to allow a user to carry or otherwise bring with the computing device while in a mobile setting, while other computing devices may not be portable but allow a user to utilize the computing device in an office or home setting. Certain computing devices may utilize swappable integrated circuit cards to enable various types of functionality for use for work, education, gaming, multimedia, and/or other general use.

### BRIEF DESCRIPTION OF THE DRAWINGS

FIG. 1 is a top perspective view of an example of a locking card tray consistent with the disclosure.

FIG. 2A is a bottom perspective view of an example of a locking card tray having an elastic deformable member with a half-spherical protrusion consistent with the disclosure.

FIG. 2B is a bottom perspective view of an example of a locking card tray having an elastic deformable member with a triangular prism protrusion consistent with the disclosure.

FIG. 3 is a top perspective view of an example of a locking card tray having an integrated circuit card consistent with the disclosure.

FIG. 4A is a side view of an example of a locking card tray having an elastic deformable member in a first position consistent with the disclosure.

FIG. 4B is a side view of an example of a locking card tray having an elastic deformable member in a second position consistent with the disclosure.

FIG. 5A is a side-section view of an example of a locking card tray and a computing device having a tray housing including a locking mechanism consistent with the disclosure,

FIG. 5B is a detail side-section view of an example of a computing device having a tray housing including a locking mechanism receiving a locking card tray having an elastic deformable member deforming the locking mechanism consistent with the disclosure.

FIG. 5C is a side-section view of an example of a computing device having a tray housing including a locking mechanism locking a locking card tray in the tray housing via a slot in an elastic deformable member consistent with the disclosure.

FIG. 5D is a side-section view of an example of a computing device having a tray housing including a locking mechanism locking a locking card tray in the tray housing via an end surface of an elastic deformable member consistent with the disclosure.

FIG. 6 is a top perspective view of an example of a locking card tray having an elongated side deformable member consistent with the disclosure.

FIG. 7 is a top view of an example of a computing device having a tray housing receiving a locking card tray having an elongated side deformable member consistent with the disclosure.

### DETAILED DESCRIPTION

A user may utilize a computing device for various purposes, such as for business and/or recreational use. As used herein, the term “computing device” refers to an electronic system having a processor resource and a memory resource. Examples of computing devices can include, for instance, a laptop computer, a notebook computer, a desktop computer, an all-in-one (AIO) computer (e.g., a computing device in which computing hardware and a display device are included in a single housing), among other types of computing devices.

As mentioned above, the computing device may utilize an integrated circuit card for various purposes. As used herein, the term “integrated circuit card” refers to a set of electronic circuits located on a semiconductor material. Examples of an integrated circuit card can include, for instance, memory cards and/or microprocessor cards, among other examples. For instance, the computing device may utilize a memory card (e.g., such as a secure digital (SD) card) to store data. As another example, the computing device may utilize a microprocessor card for wireless (e.g., mobile) communication capabilities.

In some examples, the computing device may include mobile device communication capabilities. For example, the computing device may communicate with other computing devices via a mobile/cellular communications network. Such a network may include a 3G network, a Long Term Evolution (LTE) network (e.g., a 4G network), a 5G network, among other types of cellular communication networks.

In order to communicate on such cellular communication networks, the computing device may include a type of integrated circuit card, such as a microprocessor card, to enable such wireless communication over the cellular communication networks. The integrated circuit card can be, for example, a universal integrated circuit card (UICC), a Subscriber Identity Model (SIM) card, among other examples. As used herein, the term “UICC” refers to an integrated circuit card used in a mobile terminal in a cellular communication network. As used herein, the term “SIM card” refers to an integrated circuit to securely store an international mobile subscriber identity (IMSI) number and its related key. In some examples, a SIM card can be a component of a UICC. An IMSI number and key of a SIM card can identify and authenticate subscribers to a cellular communication network and allow the computing device to communicate with other computing devices via the cellular communication network.

In some examples, an administrator of the computing device may wish to prevent a user of the computing device from removing the integrated circuit card from the computing device. For example, such a computing device may be utilized in an educational environment where an administrator may wish to prevent students from removing the integrated circuit card from the computing device. Such removal prevention of the integrated circuit card can prevent damage to the integrated circuit card, prevent the computing device from being utilized in unintended or unauthorized ways, etc.

Locking card trays according to the disclosure can allow for an integrated circuit card to be secured in a computing device. For example, a locking card tray can receive an integrated circuit card and can be secured in a tray housing in a way that prevents removal of the locking card tray from the tray housing. Such locking card trays can prevent unauthorized removal of the integrated circuit card.

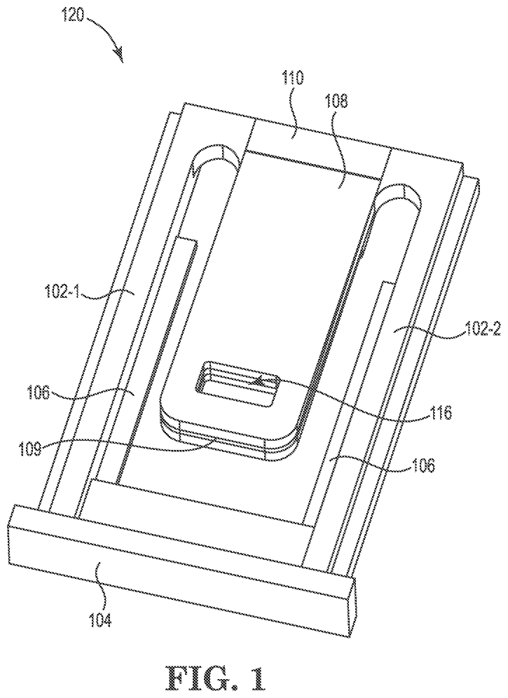

FIG. 1 is a top perspective view of an example of a locking card tray 120 for locking card trays consistent with the disclosure. As illustrated in FIG. 1, the locking card tray 120 can include a first elongated side 102-1, a second elongated side 102-2, a first end side 104, and a second end side 110.

As previously mentioned above, the locking card tray 120 can be a locking card tray to receive and secure an integrated circuit card (e.g., not illustrated in FIG. 1). The locking card tray 120 can be received by a computing device (e.g., not illustrated in FIG. 1) and, if the locking card tray 120 includes the integrated circuit card, can be locked in a tray housing of the computing device, as is further described herein.

As shown in FIG. 1, the locking card tray 120 can include a first elongated side 102-1. As used herein, the term “elongated side” refers to a bounding object having a length longer than its width. For example, the first elongated side 102-1 can be one side of a bounding geometric figure (e.g., a rectangle) that can operate to receive and secure an integrated circuit card, as is further described herein. The first elongated side 102-1 can be of a metal, plastic, and/or other composite material. The first elongated side 102-1 may be machined, extruded, three-dimensionally (3D) printed, etc.

Additionally, the locking card tray 120 can include a second elongated side 102-2. The second elongated side 102-2 can additionally be one side of a bounding geometric figure (e.g., a rectangle) that can operate to receive and secure an integrated circuit card, as is further described herein. The second elongated side 102-2 can be located opposite the first elongated side 102-1. That is, the second elongated side 102-2 can be oriented in a manner that is mirrored from but situated in a corresponding position in relation to an offset distance from the first elongated side 102-1. The second elongated side 102-2 can be of a metal, plastic, and/or other composite material. The second elongated side 102-2 may be machined, extruded, three-dimensionally (3D) printed, etc.

As illustrated in FIG. 1, the locking card tray 120 can include a first end side 104. As used herein, the term “end side” refers to a bounding object having a length longer than its width. For example, the first end side 104 can be one side of a bounding geometric figure (e.g., a rectangle) that can operate to receive and secure an integrated circuit card, as is further described herein. The first end side 104 can have a length that is less than a length of the first elongated side 102-1 and second elongated side 102-2. The first end side 104 can be connected to the first elongated side 102-1 and the second elongated side 102-2. The first end side 104 can be of a metal, plastic, and/or other composite material. The first end side 104 may be machined, extruded, three-dimensionally (3D) printed, etc.

Additionally, the locking card tray 120 can include a second end side 110, The second end side 110 can additionally be one side of a bounding geometric figure (e.g., a rectangle) that can operate to receive and secure an integrated circuit card. The second end side 110 can be located opposite the first end side 104. That is, the second end side 110 can be oriented in a manner that is mirrored from but situated in a corresponding position in relation to an offset distance from the first end side 104. The second end side 110 can be of a metal, plastic, and/or other composite material. The second end side 110 may be machined, extruded, three-dimensionally (3D) printed, etc.

Accordingly, the first elongated side 102-1, the second elongated side 102-2, the first end side 104, and the second end side 110 can form a rectangular shape. The rectangular shaped locking card tray 120 can operate to receive and secure an integrated circuit card, as is further described herein.

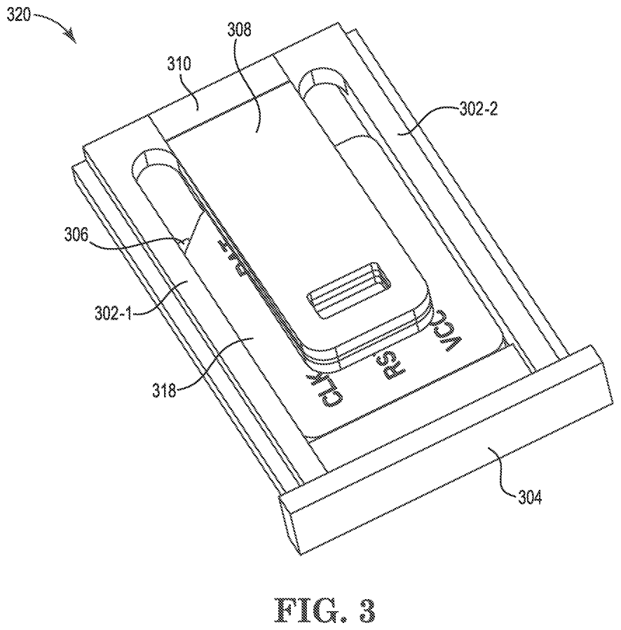

The locking card tray 120 can further include a rack tray 106. As used herein, the term “rack tray” refers to a framework of shelves to form a receptacle. For example, the rack tray 106 can receive an integrated circuit card in the locking card tray 120, as is further described in connection with FIG. 3,

To secure the integrated circuit card in the locking card tray 120, the locking card tray 120 can include an elastic deformable member 108. As used herein, the term “elastic deformable member” refers to a constituent part of a structural whole that moves from an original position when a force is applied thereto but returns to its original position when the force is removed. For example, when the locking card tray 120 receives an integrated circuit card, the elastic deformable member 108 rotates from a first position (e.g., as illustrated in FIG. 1) to a second position but returns to the first position if the integrated circuit card is removed from the locking card tray 120. The elastic deformable member 108 extends from the second end side 110 towards the first end side 104.

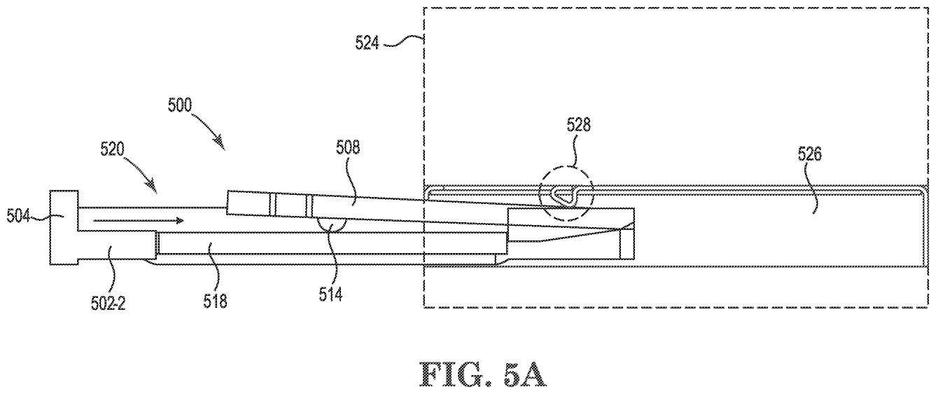

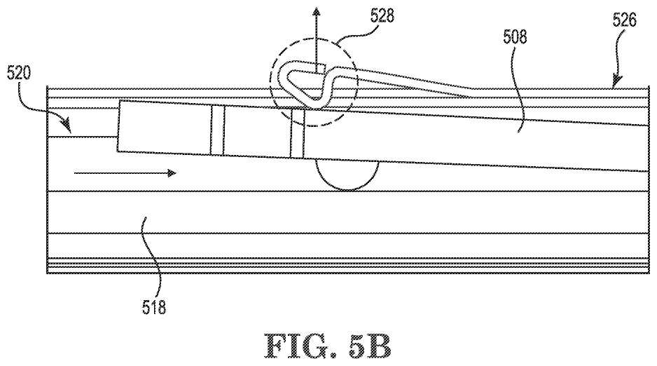

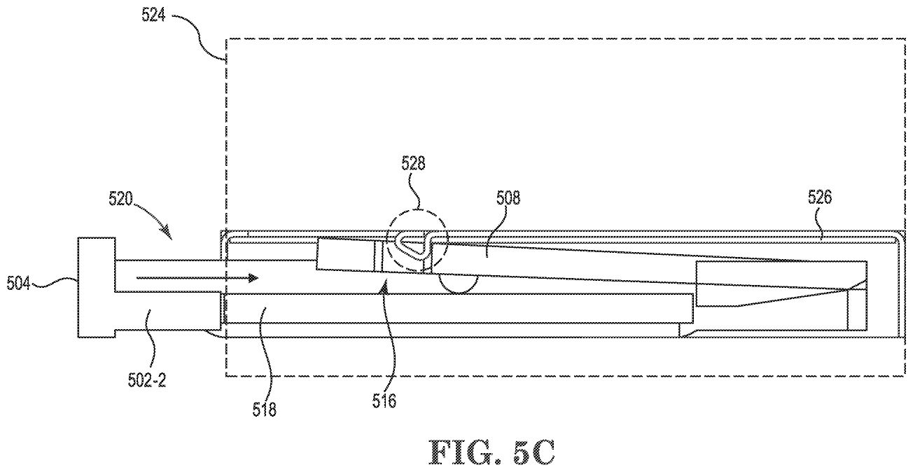

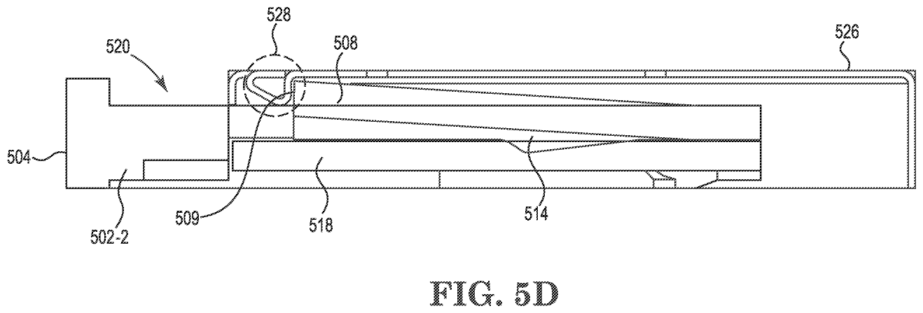

In some examples, (e.g., such as the example illustrated in FIG. 1), the elastic deformable member 108 includes a slot 116. As used herein, the term “slot” refers to an aperture through a material. For example, the slot 116 can be an opening through the material of the elastic deformable member 108. In some examples, the slot 116 can be utilized to lock the locking card tray 120 to a tray housing when the locking card tray 120 includes an integrated circuit card, as is further described in connection with FIG. 5C.

The elastic deformable member 108 can include an end surface 109. The end surface 109 can be a surface of the elastic deformable member 108 that faces the first end side 104. In some examples, the end surface 109 can be utilized to lock the locking card tray 120 to a tray housing when the locking card tray 120 includes an integrated circuit card, as is further described in connection with FIG. 5D,

As mentioned above, the locking card tray 120 as illustrated in FIG. 1 does not include an integrated circuit card. Accordingly, the elastic deformable member 108 can be in a first position such that the elastic deformable member 108 does not protrude from the locking card tray 120.

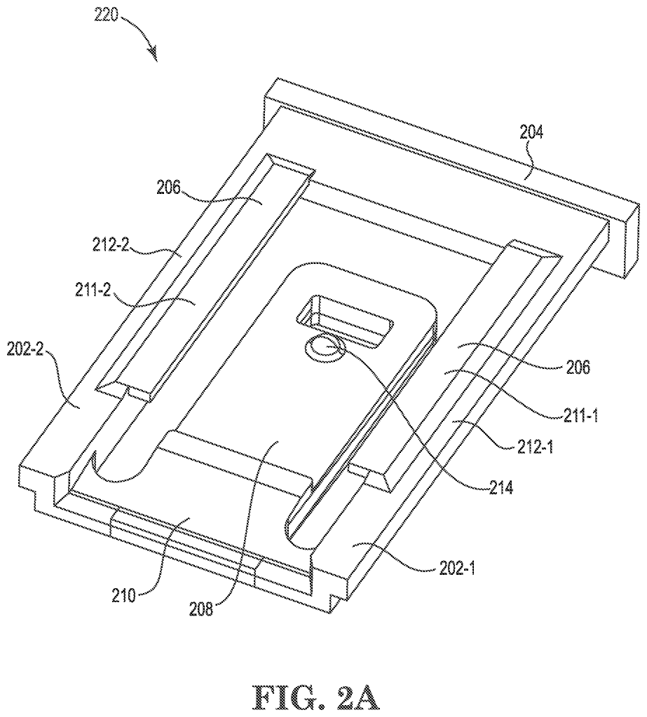

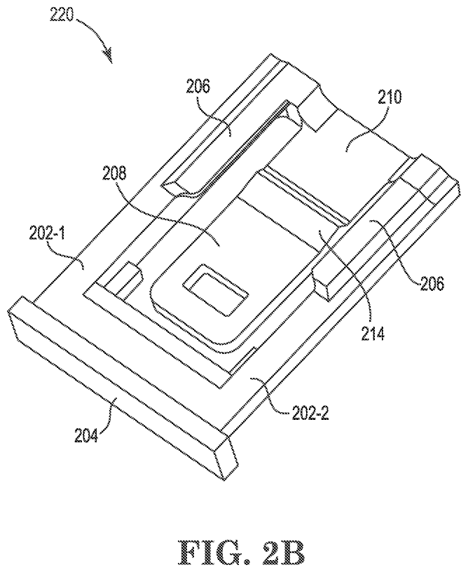

FIG. 2A is a bottom perspective view of an example of a locking card tray 220 having an elastic deformable member 208 with a half-spherical protrusion 214 consistent with the disclosure. As illustrated in FIG. 2A, the locking card tray 220 can include a first elongated side 202-1, a second elongated side 202-2, a first end side 204, and a second end side 210.

As previously described in connection with FIG. 1, the locking card tray 220 can include a first elongated side 202-1, a second elongated side 202-2, a first end side 204, and a second end side 210 forming a rectangular locking card tray 220 to receive an integrated circuit card (e.g., not illustrated in FIG. 2A).

As previously mentioned in FIG. 1, the locking card tray 220 can include a rack tray 206. As shown in FIG. 2A, the rack tray 206 is defined by a first protrusion 211-1 extending from a surface 212-1 of the first elongated side 202-1. The first protrusion 211-1 can be, for example, a shelf that can receive one side of an integrated circuit card. Similarly, the rack tray 206 is defined by a second protrusion 211-2 extending from a surface 212-2 of the second elongated side 202-2. The second protrusion 211-2 can also be, for example, a shelf that can receive the other side of an integrated circuit card. The second protrusion 211-2 can be located opposite the first protrusion 211-1.

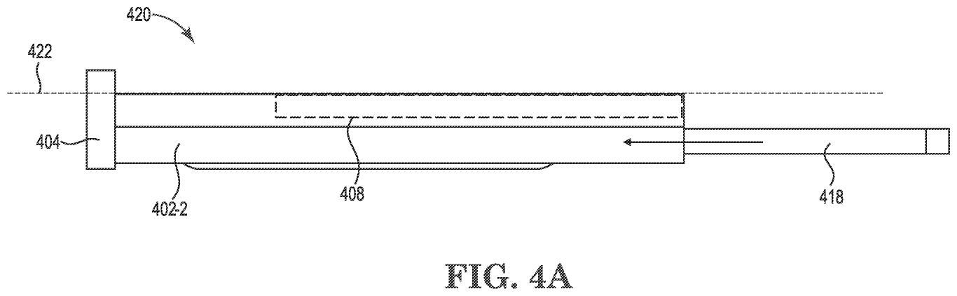

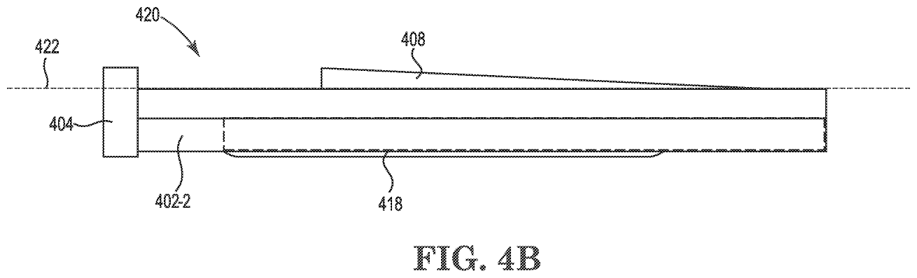

As previously described in connection with FIG. 1, the elastic deformable member 208 can extend from the second end side 210. As illustrated in FIG. 2A, the elastic deformable member 208 can include a protrusion 214. The protrusion 214 can be, in some examples, a half-spherical protrusion (e.g., a half-sphere). When the locking card tray 220 receives the integrated circuit card, the protrusion 214 can contact a surface of the integrated circuit card causing the elastic deformable member 208 to rotate from the first position (e.g., as illustrated in FIG. 2A) to a second position (e.g., as is further described in connection with FIG. 4B.

Further, while the protrusion 214 is described above as being a half-sphere, examples are not so limited. For example, the protrusion 214 can be substantially a half-sphere. As used herein, the term “substantially” intends that the characteristic does not have to be absolute but is close enough so as to achieve the characteristic. For example, “substantially half-spherical” is not limited to absolute half spherical. For instance, the protrusion 214 can be within a certain tolerance of half-spherical (e.g., slightly less than half-spherical, slightly more than half-spherical, etc,)

FIG. 2B is a bottom perspective view of an example of a locking card tray 220 having an elastic deformable member with a triangular prism protrusion 214 consistent with the disclosure. As illustrated in FIG. 2B, the locking card tray 220 can include a first elongated side 202-1, a second elongated side 202-2, a first end side 204, and a second end side 210.

Similar to the locking card trays of FIGS. 1 and 2A, the locking card tray 220 can include a first elongated side 202-1, a second elongated side 202-2, a first end side 204, and a second end side 210 forming a rectangular locking card tray 220 to receive an integrated circuit card (e.g., not illustrated in FIG. 2B). Additionally, the locking card tray 220 can include a rack tray 206 and an elastic deformable member 208 extending from the second end side 210.

As illustrated in FIG. 2B, the elastic deformable member 208 can include a protrusion 214. The protrusion 214 can be, in some examples, a triangular prism protrusion (e.g., a triangular prism). When the locking card tray 220 receives the integrated circuit card, the protrusion 214 can contact a surface of the integrated circuit card causing the elastic deformable member 208 to rotate from the first position (e.g., as illustrated in FIG. 2A) to a second position (e.g., as is further described in connection with FIG. 4B.

FIG. 3 is a top perspective view of an example of a locking card tray 320 having an integrated circuit card 318 consistent with the disclosure. As illustrated in FIG. 3, the locking card tray 320 can include a first elongated side 302-1, a second elongated side 302-2, a first end side 304, and a second end side 310.

The locking card tray 320 can include a first protrusion from a surface of the first elongated side 302-1 and a second protrusion from a surface of the second elongated side 302-2 (e.g., located opposite the first elongated side 302-1) to form a rack tray 306. The elastic deformable member 308 can extend from the second end side 310.

As illustrated in FIG. 3, the locking card tray 320 has received an integrated circuit card 318. For example, a user has inserted the integrated circuit card 318 into the locking card tray 320 and the rack tray 306 supports the integrated circuit card 318 in the locking card tray 320.

In response to the locking card tray 320 receiving the integrated circuit card 318, the elastic deformable member 308 rotates from a first position to a second position. In the second position, the elastic deformable member 308 protrudes from the locking card tray 320, as is further described in connection with FIG. 4B.

As previously mentioned above, the integrated circuit card 318 can be, for example, a SIM card. The user may insert the SIM card into the locking card tray 320 for insertion into a computing device to enable communication via the computing device over a cellular communications network.

However, examples of the disclosure are not limited to a SIM card. For instance, in some examples, the integrated circuit card 318 can be a memory card. The user may insert the memory card into the locking card tray 320 for insertion into a computing device to allow for additional memory capacity for the computing device,

FIG. 4A is a side view of an example of a locking card tray 420 having an elastic deformable member 408 in a first position consistent with the disclosure, In the example illustrated in FIG. 4A, the locking card tray 420 is in the process of receiving an integrated circuit card 418.

The locking card tray 420 can include a first elongated side (e.g., not illustrated in FIG. 4A), a second elongated side 402-2, a first end side 404, and a second end side (e.g., not illustrated in FIG. 4A).

The first elongated side and the second elongated side 402-2 can form a plane 422. As used herein, the term “plane” refers to a flat, two-dimensional surface, For example, the plane 422 can be a two-dimensional surface formed by the first elongated side and the second elongated side 402-2.

When the elastic deformable member 408 is in the first position (e.g., as illustrated in FIG. 4A), the locking card tray 420 has not received the integrated circuit card 418, Accordingly, when the elastic deformable member 408 is in the first position, the elastic deformable member 408 does not protrude from the locking card tray 420, and as such, does not protrude through the plane 422 in the first position. Rather, the elastic deformable member 408 is at the same or substantially the same height relative to the plane 422 when the elastic deformable member 408 is in the first position.

Although not illustrated in FIG. 4A, the locking card tray 420 can be received by a tray housing, In response to the tray housing receiving the locking card tray 420 when the elastic deformable member is in the first position (e.g., as illustrated in FIG. 4A), the locking card tray 420 can be removable from the tray housing. However, when the integrated circuit card 418 is received by the locking card tray 420 (e.g., causing the elastic deformable member 408 to rotate to the second position), the locking card tray 420 can be locked in the tray housing, as is further described in connection with FIGS. 5C and 5D.

FIG. 4B is a side view of an example of a locking card tray 420 having an elastic deformable member 408 in a second position consistent with the disclosure. In the example illustrated in FIG. 4B, the locking card tray 420 has received the integrated circuit card 418.

As previously described in FIG. 4A, the locking card tray 420 can be receiving an integrated circuit card 418. In response to the integrated circuit card 418 being received by the locking card tray 420 (e.g., being received by the rack tray of the locking card tray 420), the elastic deformable member 408 can rotate from the first position to a second position. For example, as the integrated circuit card 418 is slid into the locking card tray 420, the integrated circuit card 418 can contact the protrusion of the elastic deformable member 408 causing the elastic deformable member 408 to rotate to the second position.

In the second position, the elastic deformable member 408 protrudes from the locking card tray 420. As previously mentioned in FIG. 4A, the first elongated side and the second elongated side 402-2 can form a plane 422. When in the second position, the elastic deformable member 408 protrudes through the plane 422.

Although not illustrated in FIG. 4B, the locking card tray 420 can be received by a tray housing. In response to the tray housing receiving the locking card tray 420 when the elastic deformable member is in the second position (e.g., as illustrated in FIG. 4B), the locking card tray 420 can be locked in the tray housing, as is further described in connection with FIGS. 5C and 5D.

FIG. 5A is a side-section view of an example of a locking card tray 520 and a computing device 524 having a tray housing 526 including a locking mechanism 528 consistent with the disclosure. The locking card tray 520 and the tray housing 526 can comprise the apparatus 500. The locking card tray 520 can include a first elongated side (e.g., not illustrated in FIG. 5A), a second elongated side 502-2, a first end side 504, and a second end side (e.g., not illustrated in FIG.

As illustrated in FIG. 5A, the locking card tray 520 has received an integrated circuit card 518. For example, a user has inserted the integrated circuit card 518 into the locking card tray 520 and the rack tray (e.g., not illustrated in FIG. 5A) supports the integrated circuit card 518 in the locking card tray 520. As a result of the integrated circuit card 518 being inserted into the locking card tray 520, the integrated circuit card 518 contacts the protrusion 514 of the elastic deformable member 508, causing the elastic deformable member 508 to rotate to the second position such that the elastic deformable member 508 extends from the locking card tray 520 (e.g., as illustrated in FIG. 5A).

As previously mentioned above, in some examples the integrated circuit card 518 can allow for expanded memory capability for the computing device 524, communication via the computing device 524 over a cellular communications network, etc. As used herein, the term “computing device” refers to an electronic system having a processing resource, memory resource, and/or an application-specific integrated circuit (ASIC) that can process information. Examples of computing devices 524 can include, for instance, a laptop computer, a notebook computer, a desktop computer, an All-In-One (AIO) computing device, networking equipment (e.g., router, switch, etc.), and/or a mobile device, among other types of computing devices. As used herein, a mobile device can include devices that are (or can be) carried and/or worn by a user. For example, a mobile device can be a phone (e.g., a smart phone), a tablet, a personal digital assistant (PDA), smart glasses, and/or a wrist-worn device (e.g., a smart watch), among other types of mobile devices.

The computing device 524 can include a tray housing 526. As used herein, the term “tray housing” refers to an outer shell of a device. For example, the tray housing 526 can be an outer shell making up a portion of the computing device 524. The tray housing 526 can be shaped to receive the locking card tray 520. For example, a user can insert the locking card tray 520 into the tray housing 526, as illustrated in FIG. 5A. The tray housing 526 can receive the locking card tray 520 via the second end side of the locking card tray 520.

As previously mentioned above, if a user inserts the locking card tray 520 into the tray housing 526 without the integrated circuit card 518 located in the locking card tray 520, the elastic deformable member 508 can be in the first position (e.g., a non-deformed first position not protruding from the locking card tray 520) and as such, the locking card tray 520 can be removable from the tray housing 526.

The tray housing 526 can include a locking mechanism 528. As used herein, the term “locking mechanism” refers to a mechanical mechanism to couple two objects together. For example, the locking mechanism 528 can couple the tray housing 526 to the locking card tray 520, as is further described herein.

FIG. 5B is a detail side-section view of an example of a computing device having a tray housing 526 including a locking mechanism 528 receiving a locking card tray 520 having an elastic deformable member 508 deforming the locking mechanism 528 consistent with the disclosure. As illustrated in FIG. 5B, as the locking card tray 520 is inserted into the tray housing 526, the elastic deformable member 508 causes the locking mechanism 528 to deform. That is, the locking mechanism 528 rotates (e.g., upwards, as oriented in FIG. 5B) relative to the elastic deformable member 508. The locking mechanism 528 can interface with a slot (e.g., as is further described in connection with FIG. 5C) or a surface of the elastic deformable member 508 (e.g., as is further described in connection with FIG. 5D) to lock the locking card tray 520 in the tray housing 526.

FIG. 5C is a side-section view of an example of a computing device 524 having a tray housing 526 including a locking mechanism 528 locking a locking card tray 520 in the tray housing 526 via a slot 516 in an elastic deformable member 508 consistent with the disclosure, The locking card tray 520 can include a first elongated side (e.g., not illustrated in FIG. 5A), a second elongated side 502-2, a first end side 504, and a second end side (e.g., not illustrated in FIG. 5A).

As previously described in connection with FIG. 1, the elastic deformable member 508 can include a slot 516. As the locking card tray 520 is inserted into the tray housing 526, the locking mechanism 528 can interface with the slot 516. In response to the locking mechanism 528 interfacing with the slot 516, the locking mechanism 528 can lock the locking card tray 520 in the tray housing 526 (e.g., when the elastic deformable member 508 is in the deformed second position). In other words, the locking mechanism 528 can be inserted into the slot such that the locking mechanism 528 prevents lateral movement (e.g., to the left, as oriented in FIG. 5C) of the locking card tray 520.

FIG. 5D is a side-section view of an example of a computing device 524 having a tray housing 526 including a locking mechanism 528 locking a locking card tray 520 in the tray housing 526 via an end surface 509 of an elastic deformable member 508 consistent with the disclosure. The locking card tray 520 can include a first elongated side (e.g., not illustrated in FIG. 5A), a second elongated side 502-2, a first end side 504, and a second end side (e.g., not illustrated in FIG. 5A).

As previously described in connection with FIG. 1, the elastic deformable member 508 can include an end surface 509. As the locking card tray 520 is inserted into the tray housing 526, the locking mechanism 528 can interface with the end surface 509. In response to the locking mechanism 528 interfacing with the end surface 509, the locking mechanism 528 can lock the locking card tray 520 in the tray housing 526 (e.g., when the elastic deformable member 508 is in the deformed second position), In other words, the locking mechanism 528 can contact the end surface 509 such that the locking mechanism 528 prevents lateral movement (e.g., to the left, as oriented in FIG. 5D) of the locking card tray 520.

Locking card trays according to the disclosure can allow for an integrated circuit card to be secured in a tray housing of a computing device. The locking card tray can be locked in the tray housing to prevent removal of the locking card tray from the tray housing in order to prevent unauthorized removal of the integrated circuit card.

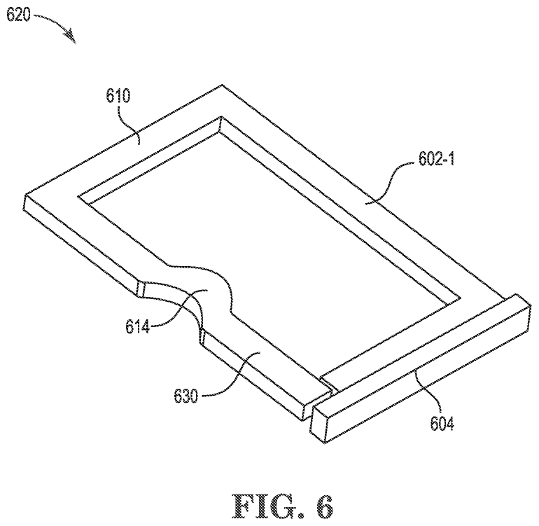

FIG. 6 is a top perspective view of an example of a locking card tray 620 having an elongated side deformable member 630 consistent with the disclosure. As illustrated in FIG. 6, the locking card tray 620 can include a first elongated side 602-1, the elongated side deformable member 630, a first end side 604, and a second end side 610.

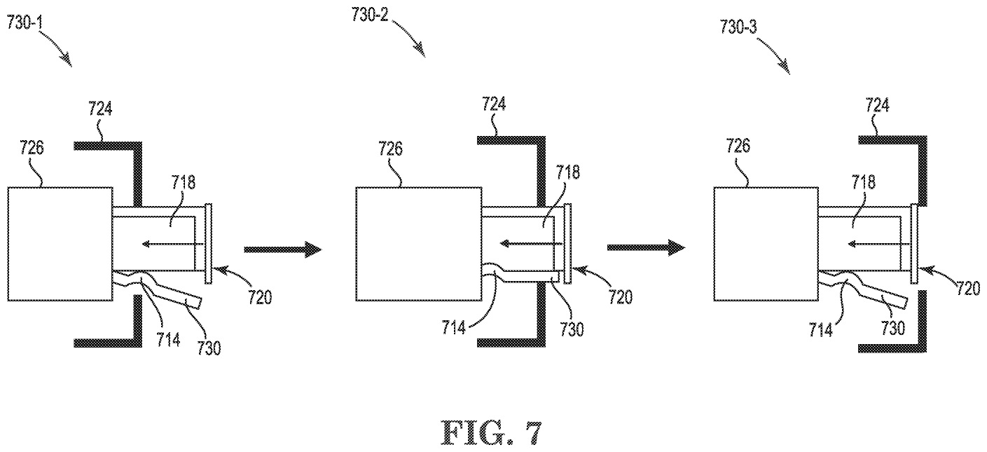

In the alternative example locking card tray 620 (e.g., from the locking card tray illustrated in FIGS. 1-5 above), the elongated side deformable member 630 can be an elongated side. The elongated side deformable member 630 can include a protrusion 614. In response to receiving an integrated circuit card (e.g., not illustrated in FIG, 6), the elongated side deformable member 630 can be deformed by the integrated circuit card. The locking card tray 620 can be locked by a computing device, as is further described in connection with FIG. 7.

FIG. 7 is a top view of an example of a computing device 724 having a tray housing 726 receiving a locking card tray 720 having an elongated side deformable member 730 consistent with the disclosure. The computing device 724 can include the tray housing 726.

At step 730-1, the locking card tray 720 has received an integrated circuit card 718, causing the elongated side deformable member 730 to deform to a second position (e.g., as a result of the integrated circuit card 718 contacting the protrusion 714). Accordingly, a user can begin to insert the locking card tray 720 into the tray housing 726.

At step 730-2, as the locking card tray 720 continues to be inserted into the tray housing 726, the computing device 724 (e.g., a housing of the computing device 724) can cause the elongated side deformable member 730 to deform to a second position. At the second position, the protrusion 714 can be deformed as a result of the contact with the integrated circuit card 718.

At step 730-3, as the locking card tray 720 continues to be inserted into the tray housing 726, the elongated side deformable member 730 is no longer in contact with the computing device 724, allowing the elongated side deformable member 730 to rotate back to the first position. In such a position, the locking card tray 720 is locked in the computing device 724, as the elongated side deformable member 730 is no longer able to be removed from the computing device 724. In such an orientation, the locking card tray 720 locks the integrated circuit card 718 in the tray housing 726, preventing unauthorized removal of the integrated circuit card 718 from the computing device 724.

In the foregoing detailed description of the disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the disclosure. Further, as used herein, “a” can refer to one such thing or more than one such thing.

The figures herein follow a numbering convention in which the first digit corresponds to the drawing figure number and the remaining digits identify an element or component in the drawing. For example, reference numeral 102 may refer to element 108 in FIG. 1 and an analogous element may be identified by reference numeral 208 in FIG. 2A. Elements shown in the various figures herein can be added, exchanged, and/or eliminated to provide additional examples of the disclosure. In addition, the proportion and the relative scale of the elements provided in the figures are intended to illustrate the examples of the disclosure, and should not be taken in a limiting sense.

It can be understood that when an element is referred to as being “on,” “connected to”, “coupled to”, or “coupled with” another element, it can be directly on, connected, or coupled with the other element or intervening elements may be present. In contrast, when an object is “directly coupled to” or “directly coupled with” another element it is understood that are no intervening elements (adhesives, screws, other elements) etc.

The above specification, examples and data provide a description of the method and applications, and use of the system and method of the disclosure. Since many examples can be made without departing from the spirit and scope of the system and method of the disclosure, this specification merely sets forth some of the many possible example configurations and implementations.

What is claimed is:

1. A locking card tray, comprising:
a first elongated side;
a second elongated side located opposite the first elongated side;
a first end side connected to the first elongated side and the second elongated side;
a rack tray; and
an elastic deformable member;
wherein in response to an integrated circuit card being received by the rack tray, the elastic deformable member is to rotate from a first position to a second position such that the elastic deformable member protrudes from the locking card tray,

2. The locking card tray of claim 1, wherein the rack tray is defined by a first protrusion from a surface of the first elongated side and a second protrusion from a surface of the second elongated side.

3. The locking card tray of claim 2, wherein the second protrusion is located opposite the first protrusion.

4. The locking card tray of claim 1, wherein the elastic deformable member includes a protrusion that contacts the integrated circuit card in response to being received by the rack tray to cause the elastic deformable member to rotate to the second position.

5. The locking card tray of claim 1, wherein:
the locking card tray includes a second end side connected to the first elongated side and the second elongated side, the second end side being opposite the first end side; and
the elastic deformable member extends from the second end side towards the first end side.

6. An apparatus, comprising:
a locking card tray, including:
a first elongated side including a first protrusion from a surface of the first elongated side;
a second elongated side located opposite the first elongated side and including a second protrusion from a surface of the second elongated side;
a first end side connected to the first elongated side and the second elongated side;
a second end side connected to the first elongated side and the second elongated side, the second end side located opposite the first end side;
a rack tray defined by the first protrusion of the first elongated side and the second protrusion of the second elongated side;
an elastic deformable member; and
a tray housing shaped to receive the locking card tray;
wherein in response to an integrated circuit card being received by the rack tray, the elastic deformable member is to rotate from a first position to a second position such that the elastic deformable member protrudes from the locking card tray.

7. The apparatus of claim 6, wherein in response to the tray housing receiving the locking card tray when the elastic deformable member is in the first position, the locking card tray is removable from the tray housing.

8. The apparatus of claim 6, wherein in response to the tray housing receiving the locking card tray when the elastic deformable member is in the second position, the locking card tray is locked in the tray housing,

9. The apparatus of claim 6, wherein the first elongated side and the second elongated side form a plane such that the elastic deformable member protrudes through the plane in the second position,

10. The apparatus of claim 6, wherein the integrated circuit card is a Subscriber Identity Model (SIM) card.

11. A computing device, comprising:
a locking card tray, including:
a first elongated side including a first protrusion from a surface of the first elongated side;
a second elongated side located opposite the first elongated side and including a second protrusion from a surface of the second elongated side;
a first end side connected to the first elongated side and the second elongated side;
a second end side connected to the first elongated side and the second elongated side, the second end side located opposite the first end side;
a rack tray defined by the first protrusion of the first elongated side and the second protrusion of the second elongated side;
an elastic deformable member; and
a tray housing shaped to receive the locking card tray;
wherein:
the elastic deformable member is normally in a non-deformed first position; and
in response to an integrated circuit card being received by the rack tray, the elastic deformable member is to rotate from the non-deformed first position to a deformed second position such that the elastic deformable member protrudes from the locking card tray.

12. The computing device of claim 11, wherein the tray housing includes a locking mechanism.

13. The computing device of claim 12, wherein the elastic deformable member includes a slot to interface with the locking mechanism to lock the locking card tray in the tray housing when the elastic deformable member is in the deformed second position.

14. The computing device of claim 12, wherein the elastic deformable member includes an end surface to interface with the locking mechanism to lock the locking card tray in the tray housing when the elastic deformable member is in the deformed second position.

15. The computing device of claim 11, wherein the tray housing is to receive the locking card tray via the second end side of the locking card tray.
